(19) United States
(12) Patent Application Publication
(10) Pub. No.: US 2026/0236078 A1
(43) Pub. Date: Aug. 13, 2026

(54) REACTIVE POWER RAIL VOLTAGE DROOP MANAGEMENT

(71) Applicant: QUALCOMM Incorporated, San Diego, CA (US)

(72) Inventor: Vijayakumar Ashok DIBBAD, Bangalore (IN)

(21) Appl. No.: 19/050,847

(22) Filed: Feb. 11, 2025

(51) Int. Cl. G06F 1/30; G01R 19/165; G06F 1/3215; G06F 1/3237; G06F 1/324

(52) U.S. Cl. CPC G06F 1/305; G01R 19/16552; G06F 1/3215; G06F 1/3237; G06F 1/324

(57) ABSTRACT

Aspects of present disclosure provide techniques for reactive Vdroop management using hysteretic thresholds. An apparatus can manage Vdroop using a hysteretic based scheme. The apparatus can monitor a power rail to detect Vdroop violations and recovery levels with high accuracy, avoiding estimation errors.

### TECHNICAL FIELD

The technology discussed below relates generally to power rail voltage droop detection and management in an apparatus, and more particularly, to a reactive scheme for managing rail voltage droop.

### INTRODUCTION

System-on-chip (SoC) technology has emerged as a key component in computing devices and mobile devices. SoC technology can integrate a large amount of functionality with heterogeneous devices on a single semiconductor device, for example, central processing units (CPUs), graphic processing units (GPUs), neural signal processors (NSPs), digital signal processors (DSPs), Double Data Rate Synchronous Dynamic Random-Access Memory (DDR SDRAM), hardware accelerators, fixed function accelerators, etc. An SoC can reduce the overall system size and cost as many components can be included on the same chip and internally connected. Performance metrics on the processing cores (e.g., GPU, CPU, NSP) are important in the SoC.

In SoC systems, where various components such as CPUs, GPUs, memory controllers, and peripheral devices share power resources, the dynamic and unpredictable nature of workload demands makes voltage droop detection and management particularly challenging. Voltage droop refers to a temporary drop in the supply voltage of a power rail below its nominal or expected level. Voltage droop is a critical concern in SoC designs, where multiple subsystems operate simultaneously and demand consistent power delivery. Excessive voltage droop can cause timing violations, data corruption, or system crashes, while overcompensating for droop can lead to inefficiencies, overheating, and increased energy consumption.

### BRIEF SUMMARY OF SOME EXAMPLES

The following presents a summary of one or more aspects of the present disclosure, in order to provide a basic understanding of such aspects. This summary is not an extensive overview of all contemplated features of the disclosure, and is intended neither to identify key or critical elements of all aspects of the disclosure nor to delineate the scope of any or all aspects of the disclosure. Its sole purpose is to present some concepts of one or more aspects of the disclosure in a form as a prelude to the more detailed description that is presented later.

Aspects of present disclosure provide techniques for reactive Vdroop management using hysteretic thresholds. An apparatus can manage Vdroop using a hysteretic based scheme. The apparatus can monitor a power rail to detect Vdroop violations and recovery levels with high accuracy, avoiding estimation errors.

In some aspects, an apparatus includes a system-on-chip (SoC) and a power management integrated circuit (PMIC) configured to supply power to the SoC. The SoC is configured to: detect a rail voltage associated with the SoC; perform a hysteretic comparison of the rail voltage to a hysteresis band; and stabilize the rail voltage based on a result of the hysteretic comparison.

In some aspects, a method of managing a rail voltage at an apparatus is provided. The method includes detecting a rail voltage associated with the apparatus; performing a hysteretic comparison of the rail voltage to a hysteresis band; and stabilizing the rail voltage based on a result of the hysteretic comparison.

In some aspects, a system on a chip (SoC) includes: means for detecting a rail voltage associated with the SoC; means for performing a hysteretic comparison of the rail voltage to a hysteresis band; and means for stabilizing the rail voltage based on a result of the hysteretic comparison.

These and other aspects will become more fully understood upon a review of the detailed description, which follows. Other aspects, features, and examples will become apparent to those of ordinary skill in the art upon reviewing the following description of specific exemplary aspects in conjunction with the accompanying figures. While features may be discussed relative to certain examples and figures below, all examples can include one or more of the features discussed herein. In other words, while one or more examples may be discussed as having certain features, one or more of such features may also be used in accordance with the various examples discussed herein. Similarly, while examples may be discussed below as device, system, or method examples, it should be understood that such examples can be implemented in various devices, systems, and methods.

### BRIEF DESCRIPTION OF THE DRAWINGS

FIG. 1 is a diagram depicting an apparatus employing a system-on-chip (SoC) according to some aspects of the present disclosure.

FIG. 2 is a diagram depicting an exemplary rail voltage management scheme according to some aspects of the present disclosure.

FIG. 3 is a chart illustrating a first example of reactive rail voltage droop detection and management using hysteretic thresholds according to some aspects of the present disclosure.

FIG. 4 is a chart illustrating a second example of reactive rail voltage droop detection and management using hysteretic thresholds according to some aspects of the present disclosure.

FIG. 5 is a chart illustrating a comparison between an existing solution and a reactive Vdroop management scheme according to some aspects of the present disclosure.

FIG. 6 is a block diagram illustrating an exemplary hysteresis comparator according to some aspects of the present disclosure.

FIG. 7 is a flow chart illustrating a process of reactively managing rail voltage events in an apparatus according to some aspects of the present disclosure.

FIG. 8 is a diagram illustrating an exemplary method for reactively managing a rail voltage at an apparatus according to some aspects of the present disclosure.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well-known structures and components are shown in block diagram form in order to avoid obscuring such concepts.

Several aspects of the invention will now be presented with reference to various apparatus and methods. These apparatus and methods will be described in the following detailed description and illustrated in the accompanying drawings by various blocks, modules, components, circuits, steps, processes, algorithms, etc. (collectively referred to as “elements”). These elements may be implemented using electronic hardware, computer software, firmware, or any combination thereof. Whether such elements are implemented as hardware or software depends upon the particular application and design constraints imposed on the overall system.

While aspects and examples are described in this application by illustration to some examples, those skilled in the art will understand that additional implementations and use cases may come about in many different arrangements and scenarios. Innovations described herein may be implemented across many differing platform types, devices, systems, shapes, sizes, and packaging arrangements. For example, aspects and/or uses may come about via integrated chip examples and other non-module-component-based devices (e.g., end-user devices, vehicles, communication devices, computing devices, industrial equipment, retail/purchasing devices, medical devices, artificial intelligence (AI)-enabled devices, etc.). While some examples may or may not be specifically directed to use cases or applications, a wide assortment of applicability of described innovations may occur. Implementations may range in spectrum from chip-level or modular components to non-modular, non-chip-level implementations and further to aggregate, distributed, or original equipment manufacturer (OEM) devices or systems incorporating one or more aspects of the described innovations. In some practical settings, devices incorporating described aspects and features may also necessarily include additional components and features for the implementation and practice of described examples. It is intended that innovations described herein may be practiced in a wide variety of devices, chip-level components, systems, distributed arrangements, end-user devices, etc., of varying sizes, shapes, and constitution.

A computing apparatus, such as a mobile device (e.g., user equipment (UE)), may include a system-on-chip (SoC), which includes a plurality components, for example, a central processing unit (CPU), a graphics processing unit (GPU), a neural signal processor (NSP), a transceiver, a modem, a digital signal processor (DSP), dynamic random access memory (DRAM), synchronous DRAM (SDRAM), etc. The apparatus can include one or more power management integrated circuits (PMICs) to control power delivery to various components (e.g., CPU, GPU, NSP, etc.) and circuitry of the apparatus. Each PMIC can manage power through one or more regulators tailored to different parts or power domains of the apparatus. Each power domain can be responsible for a specific voltage or current requirement, catering to distinct blocks or subsystems in the apparatus. Each PMIC can provide power to one or more power domains. In one example, the apparatus can use a first power domain to control power delivery to the processing cores (e.g., CPU, GPU), a second power domain to control power delivery to peripherals, and a third power domain to control power delivery to various types of memory (e.g., SRAM, DRAM), etc.

In this disclosure, the term PMIC refers to an integrated circuit or solid state device that performs various functions related to power management. A PMIC may provide one or more of the following functions, for example, DC-to-DC conversion, battery charging, power-source selection, voltage scaling, power sequencing, etc. The PMIC controls the flow and direction of electrical power in the system.

In a computing apparatus, the PMIC can control the delivery of one or more variable voltages and/or currents to various components (e.g., CPU, GPU, NSP, peripherals, etc.) and/or subsystems. When there are rapid changes in current (i) demand over time (t) within the apparatus, which can be caused by high-speed switching or load variations in the apparatus, these changes can cause fluctuations in current demand (di/dt). Voltage droop (Vdroop) can occur in some cases, for example, when there is a sudden and large increase in current demand. Vdroop refers to a temporary drop in the output voltage (rail voltage) of a power supply (e.g., PMIC) when there is a sudden increase in the load current demand. The power supply may struggle to maintain a stable voltage output, causing a temporary Vdroop. Excessive Vdroop can result in higher power consumption and potential operational instability. In order to handle Vdroop, the apparatus can use higher voltage margins which can lead to inefficiencies.

In some cases, the apparatus can use voltage setpoint uplift techniques to handle Vdroop. For example, a voltage rail can use a higher initial voltage setpoint to ensure the minimum voltage required for timing and functionality is met during voltage droops. This “uplift” avoids the risks of timing failures caused by Vdroop. In some examples, dedicated rails can dynamically adjust voltage to mitigate droop at the die level. In some examples, extra capacitors or higher PMIC phase counts can stabilize voltage levels and reduce Vdroop current during high current events. In some examples, the apparatus can proactively cut down subsystem performance to reduce current load. However, the above techniques introduce power/performance penalty, voltage overshoots, and/or cost increase.

In some examples, an apparatus can use a dynamic power management (DPM) based scheme to manage Vdroop. A DPM scheme can manage Vdroop using current throttling and slew rate limiting techniques. However, DPM based techniques can reduce system performance and require system characterization for different system designs. The DPM scheme can throttle the current consumption within a specified threshold during a single time slot such that sudden spikes (di/dt) in load current can be managed without overloading the power supply (e.g., PMIC). The DPM scheme can use a slew rate limiter to control how much current increase is allowed in each time slot, effectively smoothing transitions to avoid resonance or overshoots in the power supply. The slew rate limiter can also update the current threshold over successive time slots to regulate how quickly the load can ramp up or down. However, time-slot-based control schemes and DPM approaches are pessimistic and inefficient. They require significant manual effort and are not scalable across diverse use cases. Smarter, more adaptive power management solutions are needed to address these limitations effectively.

Aspects of present disclosure provide techniques for reactive Vdroop management using hysteretic thresholds. An apparatus can manage Vdroop using a hysteretic based scheme. The apparatus can monitor a power rail to detect Vdroop violations and recovery levels with high accuracy, avoiding estimation errors.

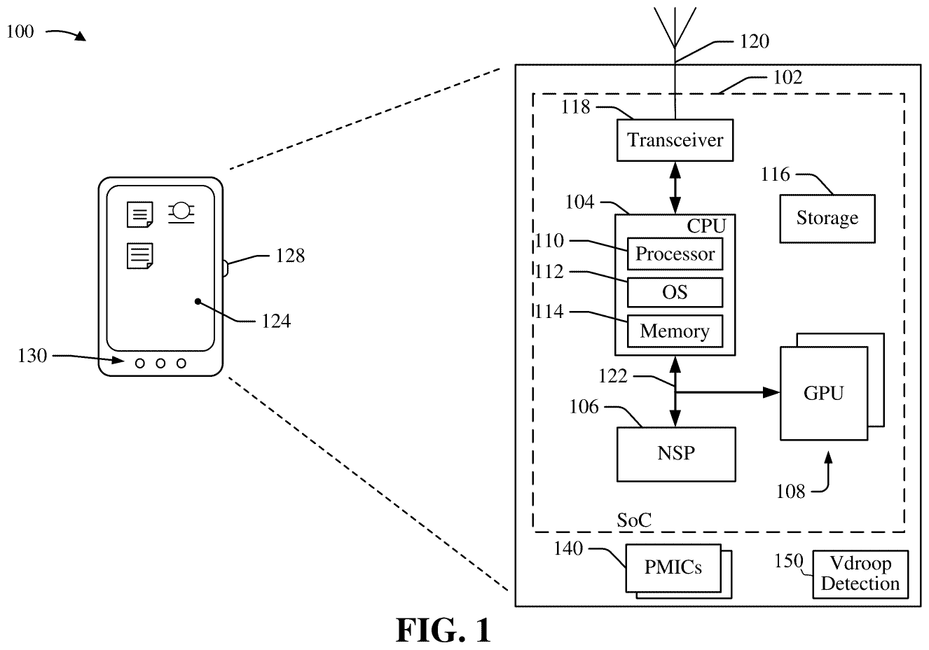

FIG. 1 is a diagram depicting an apparatus employing a system-on-chip (SoC) according to some aspects. In one example, the apparatus 100 may include a radio communication device that communicates through a radio frequency (RF) communications transceiver 118 with a radio access network (RAN), a core access network, the Internet and/or another network. The communications transceiver 118 may be embodied in, or operably coupled to an SoC 102 (the former being illustrated). The SoC 102 may include various components including various processing cores (e.g., CPU 104, NSP 106, and GPU(s) 108). In one example, the CPU 104 may include one or more processors 110 and memory 114 (e.g., L1 and/or L2 caches or registers or RAM), and may be controlled by an operating system 112 that is loaded from internal or external storage as data and instructions that are executable by the processor 110. The SoC 102 may further include or access a local storage 116, which can be used to maintain operational parameters and other information (e.g., database) used to configure and operate the apparatus 100. The local storage 116 may be implemented as a set of registers, or may be implemented in flash memory, magnetic media, non-volatile or persistent storage, optical media, tape, soft or hard disk, or the like. The SoC 102 may also be operably coupled to internal and/or external devices such as an antenna 120, a display/user interface 124, operator controls, such as buttons 128, 130, and other components.

A data communication interface (e.g., bus) 122 may be provided to support communication between the various components 104, 106, 108, and/or one or more peripherals (not shown). The data communication interface 122 may be operated in accordance with standard protocols defined for interconnecting certain components of mobile devices. For example, there may be multiple types of interfaces defined for communications between CPU 104, a user interface, and camera components of a mobile device.

In some aspects, the apparatus 100 has one or more PMICs 140, each controlling one or more power domains. Each PMIC manages power delivery in a corresponding power domain through one or more regulators tailored to that power domain. For example, different PMICs can manage power of different cores or processors (e.g., CPU 104, NSP 106, and GPU 108). In some aspects, the apparatus can include Vdroop detection circuitry 150 that uses a reactive scheme to detect and manage power rail Vdroop using hysteretic thresholds. Vdroop detection circuitry 150 may be integrated with SoC 102, PMICs 140, or standalone.

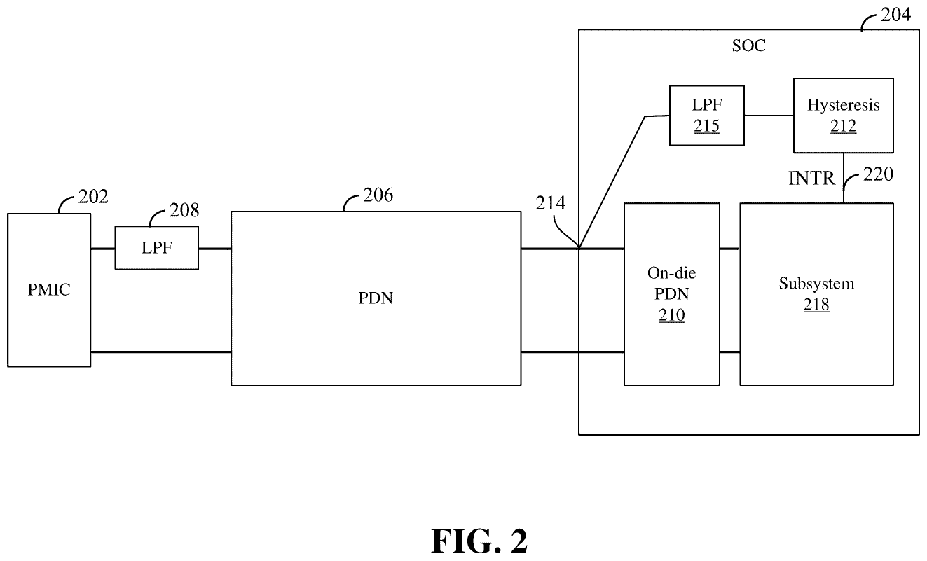

FIG. 2 is a block diagram depicting an exemplary rail voltage management scheme according to some aspects. A PMIC 202 can supply power to an SoC 204 or a subsystem of an SoC using a power delivery network (PDN) 206. A low pass filter (LPF) 208 can filter out high-frequency noise or transients from the PMIC's output before it is supplied to the PDN 206. The LPF 208 can help maintain stability in the power delivery path by smoothing voltage variations.

The PDN 206 can include various electrical components, for example, capacitors, resistors, and inductors. The PDN can be implemented using a printed circuit board (PCB) that uses power planes to distribute power from the PMIC across the PCB. The PCB can include electrical traces, vias, and planes that form the capacitive, resistive, and inductive components. The SoC 204 can include an on-die PDN 210 that supplies power to one or more subsystems 218 (e.g., components in SoC 102 of FIG. 1) that share the same power rail from the PMIC 202. For example, the on-die PDN 210 can provide power distribution paths integrated directly onto the die or chiplet of the SoC. The on-die PDN is responsible for distributing power from external sources (e.g., PMIC 202 and PDN 206) to the various components and subsystems within the SoC, including for example CPUs, GPUs, memory, and other functional blocks.

The SoC 204 may include LPF circuitry 215 that filters out high-frequency noise or transients from the power rail before it is supplied to hysteresis circuitry 212. In some aspects, the hysteresis circuitry 212 can be included in the Vdroop detection circuitry 150 of FIG. 1. The LPF circuitry 215 can sample the rail voltage at or near an entry point 214 where the PDN 206 connects to the on-die PDN 210. In this case, the LPF circuitry 215 can determine the voltage of the PMIC power rail before other components (e.g., subsystem 218) of the SoC 204.

In some aspects, the SoC can manage Vdroop using the hysteresis circuitry 212 and an interrupt (INTR) mechanism. The hysteresis circuitry 212 receives the filtered power rail voltage filtered by the LPF circuitry 215. The hysteresis circuitry 212 can monitor the power rail to detect Vdroop violations and recovery levels with high accuracy, avoiding estimation errors. In some aspects, the hysteresis circuitry 212 can provide programmable threshold levels that enable customization for specific operational requirements, ensuring precise control over voltage stability at the power rail. When the hysteresis circuitry 212 detects a Vdroop event, it triggers an output signal (e.g., INTR signal 220) to prompt the SoC (e.g., subsystem 218) to take corrective action. For example, in response to the INTR signal, the SoC/subsystem can reactively adjust (e.g., hold or reduce) its performance level as needed in order to control the rail current. By dynamically steering the rail current, the SoC can effectively manage sudden load transitions, stabilizing the rail current, and avoiding excessive voltage fluctuations. The combination of accurate Vdroop detection, programmable thresholds, and reactive rail control ensures optimal stability and efficiency for high-performance and dynamic workloads.

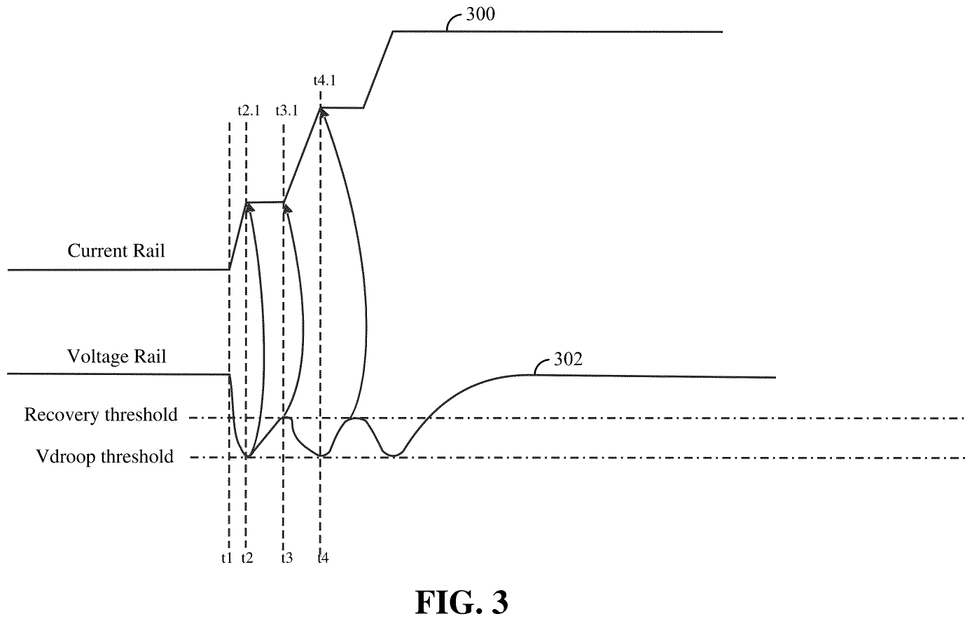

FIG. 3 is a chart illustrating a first exemplary reactive scheme of rail Vdroop detection and management using hysteretic thresholds according to some aspects. The chart illustrates the dynamic interaction between the rail current 300 and rail voltage 302 under transient conditions and demonstrates how an SoC manages Vdroop events and recovery using hysteretic thresholds.

At time t1, a change in rail current can induce a voltage droop at time t2. For example, a sudden increase in current demand in an SoC subsystem can cause a transient voltage droop (Vdroop) on the voltage rail. This occurs because the power supply (e.g., PMIC 202 of FIG. 2) and/or PDN cannot instantly accommodate the rapid change in current demand. In one example, when Vdroop exceeds a specific threshold (e.g., −40 mV), it can affect stable system operation. For example, the hysteresis circuitry 212 of FIG. 2 can be configured to determine whether the Vdroop reaches or exceeds the predetermined Vdroop threshold.

At time t2, the hysteretic circuitry can detect the Vdroop event and trigger performance limitation at time t2.1. The hysteretic circuitry can identify the Vdroop violation when the rail voltage falls below a predefined Vdroop threshold. The hysteretic circuitry promptly sends a rail event signal (e.g., signal INTR 220 of FIG. 2) to the SoC or its subsystem to limit or reduce its operating performance level in order to reduce current demand and stabilize the rail voltage. This reactive mechanism ensures rapid response to Vdroop events and prevents further instability due to excessive Vdroop. In response to the rail event signal, the SoC/subsystem is configured to react quickly (e.g., within three clock cycles) to reduce its performance level. This quick response reduces the load on the power rail, allowing the rail voltage to begin recovering from time t2.

In some aspects, an SoC/subsystem can adjust its performance level to reduce rail current through various power and performance management techniques. In one example, the SoC/subsystem can reduce its operating voltage and/or clock frequency (e.g., CPU or GPU clock frequency) to lower power consumption and, consequently, rail current. In some aspects, the SoC/subsystem can limit the number of active cores or reduce their processing load. For example, the SoC/subsystem can reduce the workload assigned to one or more cores by pausing non-essential tasks. In some aspects, the SoC/subsystem can turn off the clock signal to specific blocks or subsystems when they are idle or not needed. For example, if a subsystem like the GPU is idle, the clock signal can be gated (disabled), reducing its power consumption. In some aspects, the SoC/subsystem can power down inactive blocks or subsystems. For example, when a peripheral (e.g., a data communication module) is not in use, the SoC/subsystem can disconnect its power supply. Other ways of reducing rail current or load at the SoC/subsystem are also contemplated in this disclosure.

At time t3, the rail voltage recovers and returns to an acceptable level (e.g., recovery threshold). Then, at time 3.1, when the hysteresis circuitry 212 detects the recovery event, the hysteretic circuitry can signal the SoC/subsystem to release the performance limitation, enabling the SoC/subsystem to resume normal operation. This process can minimize performance impact by restoring peak performance as soon as rail stability is reestablished. At time t4, a subsequent increase in current demand can induce another Vdroop event. The hysteretic circuitry again detects the voltage violation and triggers the SoC/subsystem to limit its performance, repeating the above Vdroop management cycle at time t4.1 onward.

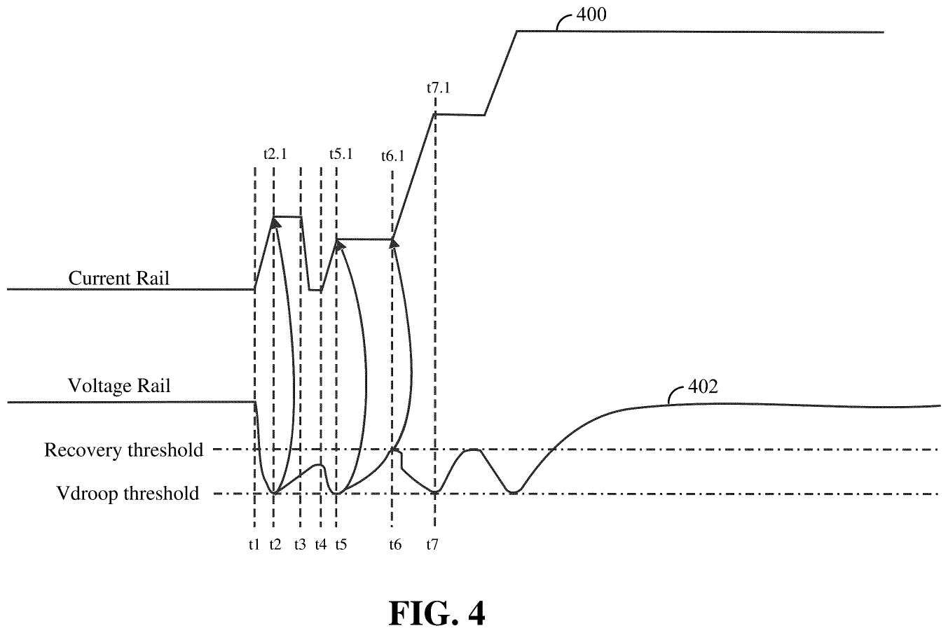

FIG. 4 is a chart illustrating a second exemplary reactive scheme of rail Vdroop detection and management using hysteretic thresholds according to some aspects. The chart illustrates the dynamic interaction between rail current 400 and rail voltage 402 under transient conditions and demonstrates how hysteretic circuitry and the SoC manage Vdroop events and recovery using hysteretic thresholds.

At time t1, a change in rail current can induce a Vdroop at time t2. For example, a sudden increase in current demand from a SoC subsystem can cause a transient Vdroop on the voltage rail. This occurs because the power supply (e.g., PMIC 202 of FIG. 2) and/or PDN cannot instantly accommodate the rapid change in current demand. In one example, when Vdroop exceeds a specific threshold (e.g., −40 mV), it can affect stable system operation.

At time t2, the hysteresis circuitry 212 (FIG. 2) can detect the Vdroop event and trigger performance limitation at time t2.1. The hysteretic circuitry can identify the Vdroop violation when the rail voltage falls below a predefined Vdroop threshold. The hysteretic circuitry promptly sends a rail event signal (e.g., INTR 220 of FIG. 2) to the SoC or its subsystem to limit or reduce its operating performance level in order to reduce current demand and stabilize the rail voltage. This reactive mechanism ensures rapid response to Vdroop events and prevents further instability due to excessive Vdroop. In response to the rail event signal, the SoC/subsystem is configured to react quickly (e.g., within three clock cycles) to adjust (e.g., hold or reduce) its performance level. This immediate response reduces the load on the rail, allowing the rail voltage to begin recovering from time t2.

In the period from t3 to t4, the SoC/subsystem can have decreasing current demand due to lower activity level and the rail voltage continues to recover. At time t4, the rail voltage can drop again due to increasing activity of the SoC/subsystem, causing increasing current demand. At time t5, the hysteretic circuitry can detect another Vdroop event and again trigger performance limitation at time t5.1. Again, the hysteretic circuitry can send a rail event signal (e.g., interrupt signal INTR 213 of FIG. 2) to the SoC/subsystem to limit or reduce its operating performance level in order to reduce current demand and stabilize the rail voltage. In response, the SoC/subsystem reacts quickly (e.g., within three clock cycles) to reduce its performance level. This immediate response reduces the load on the rail, allowing the rail voltage to begin recovering during the period from t5 to t6. The SoC/subsystem can operate at different performance levels in response to different Vdroop events.

At time t6, the rail voltage recovers and returns to an acceptable level (e.g., higher than a recovery threshold). Then, at time t6.1, when the hysteretic circuitry detects the recovery event, the hysteretic circuitry can signal the SoC/subsystem to release the performance limitation, enabling the SoC/subsystem to resume normal operation. This process can minimize performance impact by restoring peak performance as soon as rail stability is reestablished. At time t7, a subsequent increase in current demand can induce another Vdroop event. The hysteretic circuitry again detects the voltage violation and triggers the SoC/subsystem to limit its performance, repeating the above Vdroop management cycle at time t7.1 onward.

The above-described reactive rail voltage management techniques can optimize SoC performance by dynamically and selectively managing rail current and voltage, ensuring that only problematic Vdroop scenarios are mitigated while maintaining high efficiency and stability for the rest.

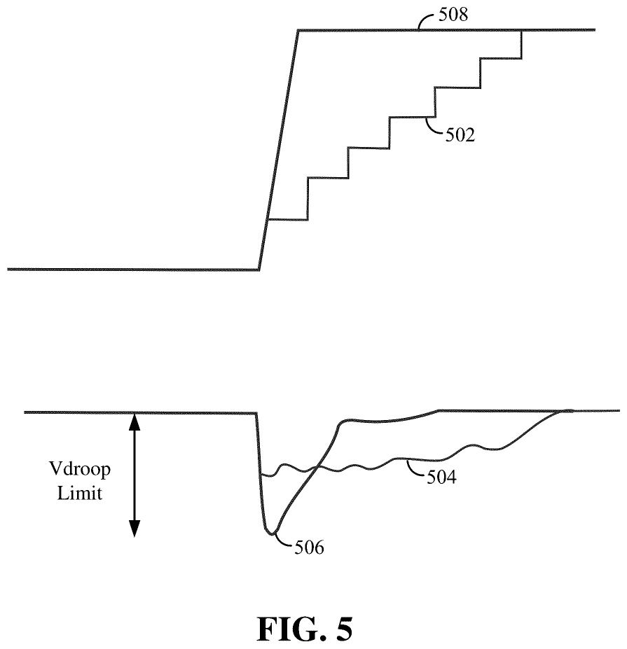

FIG. 5 is a chart illustrating different Vdroop management schemes according to some aspects. A first rail current load profile 502 uses multiple steps to increase rail current without causing Vdroop violations in rail voltage 504. However, this scheme excessively throttles performance, even when there is no Vdroop problem. In this case, the corresponding rail voltage 504 does not reach the Vdroop threshold limit. Therefore, the first rail current load profile 502 is overly conservative, leading to inefficiency in power delivery and performance management.

In some aspects, the present disclosure provides a rail voltage management scheme that is aware of actual rail Vdroop 506 and selectively applies performance throttling (e.g., holding rail current 508) only to rail current load scenarios that cause excessive Vdroop. Rail current load profiles that do not result in Vdroop violations are left unconstrained, allowing for better system performance and enhanced efficiency in power management by focusing corrective measures only on problematic load scenarios.

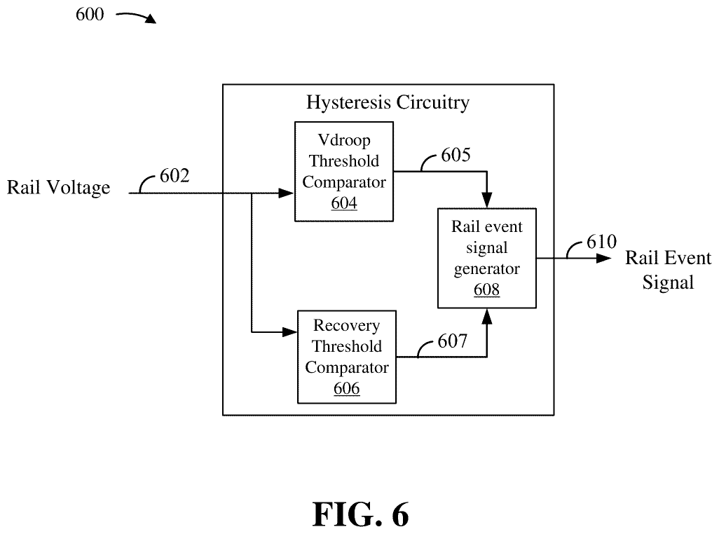

FIG. 6 is a block diagram illustrating exemplary hysteresis circuitry 600 according to some aspects. In one example, the hysteresis circuitry 600 can be included in the hysteresis circuitry 212 of FIG. 2 that can be used to monitor rail voltage as described above in relation to FIGS. 2-5.

The hysteresis circuitry 600 can monitor an input signal (e.g., rail voltage 602). For example, the hysteresis circuitry can include a Vdroop threshold comparator 604 and a recovery threshold comparator 606. When the input signal is equal to or falls below the a predefined Vdroop threshold, the Vdroop threshold comparator 604 can generate a Vdroop output signal 605, indicating a Vdroop event. Similarly, when the input signal is equal to or exceeds a recovery threshold, the recovery threshold comparator 606 can generate a recovery output signal 607, indicating a recovery event. The output signals 605 and 607 can be processed by rail event signal generator 608 that is configured to generate a rail event signal 610 based on the outputs from the Vdroop threshold comparator and recovery threshold comparator. For example, the rail event signal 610 can be signal INTR 220 of FIG. 2. The hysteresis circuitry 600 enables the apparatus to dynamically manage or react to rail events efficiently. In one example, the rail event signal can have a first level (e.g., “high” or “1) to indicate the existence of a Vdroop event or recovery event. In response to the rail event signal, the SoC/subsystem can check the rail voltage level and take corrective action accordingly. For example, Table 1 below can be used for determining the output of the rail event signal generator 608 based the outputs of the Vdroop threshold comparator and recovery threshold comparator. The value “0” indicates no event occurred, the value “1” indicates an occurrence of a voltage event. The voltage event can be caused by Vdroop or recovery.

TABLE 1

| Vdroop threshold | Recovery threshold | |
|---|---|---|
| comparator output | comparator output | Rail event |
| 0 | 0 | No event |
| 0 | 1 | Event occurred |
| 1 | 0 | Event occurred |
| N/A | N/A | N/A |

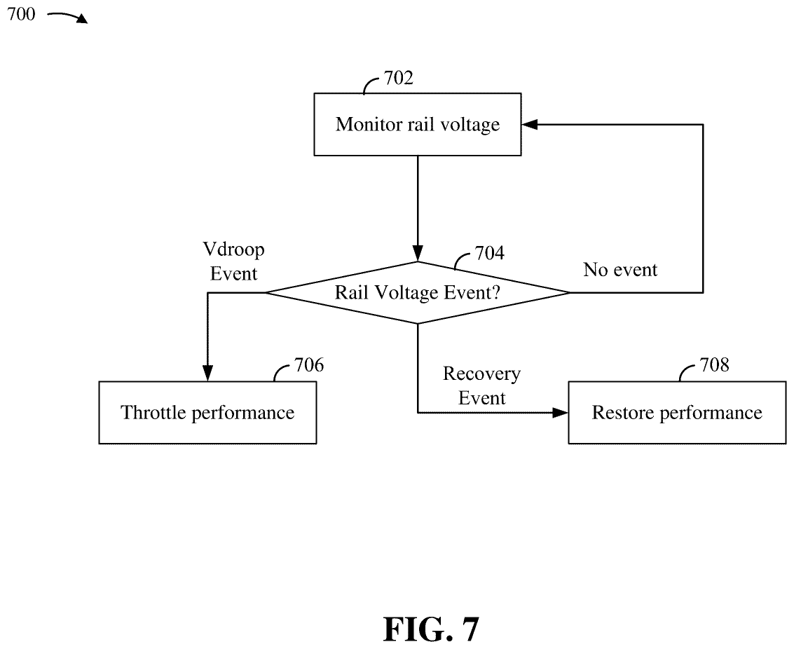

FIG. 7 is a flow chart illustrating a process 700 of reactively managing power rail events at an apparatus according to some aspects. For example, an SoC (e.g., SoC 204 of FIG. 2) or its subsystem can use this process for reactively monitoring and managing rail voltage in response to rail events such as Vdroop and recovery.

At 702, the process can monitor a rail voltage. For example, the process can continuously monitor the rail voltage to detect voltage variations caused by changes in current load or transient conditions at the SoC/subsystem. In one example, the process can use the hysteresis circuitry 600 of FIG. 6 to monitor the rail voltage.

At 704, the process can evaluate whether the rail voltage has experienced a rail voltage event, such as a Vdroop or recovery, relative to predefined thresholds (e.g., Vdroop threshold and recovery threshold). In one example, the process can use the rail event signal 610 of FIG. 6 to determine whether a Vdroop event or recovery event occurred according to Table 1. If no event is detected, the process can continue to monitor the rail voltage.

At 706, if a Vdroop event is detected, the process can throttle the performance of the SoC/subsystem. Here, the SoC or subsystem can reduce its operating performance level to decrease current demand, stabilizing the rail voltage. This response helps to mitigate instability caused by excessive load-induced voltage droop. At 708, if a recovery event is detected, the process can resume the normal performance level of the SoC/subsystem, ensuring that full functionality and efficiency are restored as soon as rail voltage stability is reestablished.

The above-described process 700 provides a reactive mechanism that dynamically adjusts system performance in response to real-time rail voltage conditions. The integration of monitoring, event detection, and performance adjustment ensures a balance between system stability and optimal performance, making this process highly suitable for systems with variable and dynamic workloads.

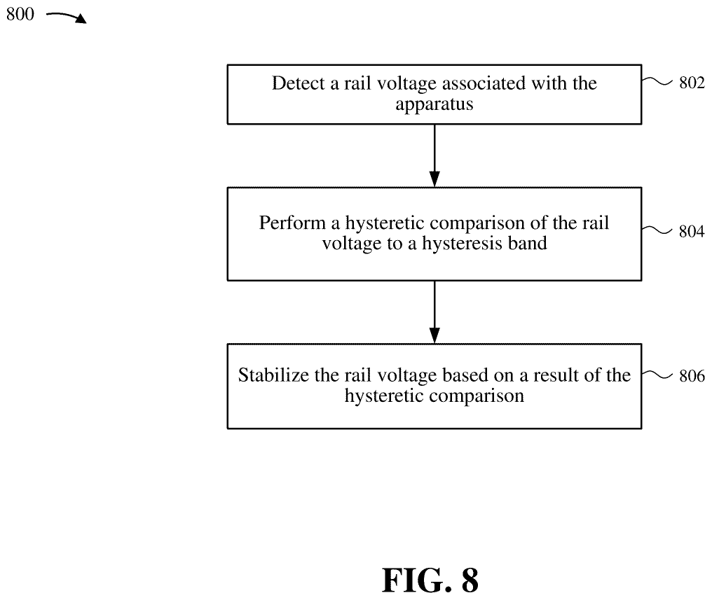

FIG. 8 is a diagram illustrating an exemplary method 800 for reactively managing a rail voltage at an apparatus according to some aspects. As described below, some or all illustrated features may be omitted in a particular implementation within the scope of the present disclosure, and some illustrated features may not be required for implementation of all embodiments. In some examples, the method 800 may be carried out by the apparatus or SoC illustrated in FIGS. 1 and 2. In some examples, the method 800 may be carried out by any suitable apparatus or means for carrying out the functions or algorithm described below.

At 802, the method includes a process of detecting a rail voltage associated with the apparatus. In one example, the apparatus can be apparatus 100 of FIG. 1 or an SoC (SoC 204 of FIG. 2) or a subsystem (e.g., subsystem 218 of FIG. 2) of the apparatus 100. In one aspect, the hysteresis circuitry 212 and/or LPF 215 of FIG. 2 can provide a means for detecting the rail voltage associated with the apparatus. In one example, the hysteresis circuitry can detect a rail voltage at a power entry point 214 of an on-die PDN 210 of the SoC of FIG. 2. In some aspects, the method can include a process of sampling the rail voltage using a filter (e.g., LPF 215 of FIG. 2) before the hysteresis circuitry.

At 804, the method includes a process of performing a hysteretic comparison of the rail voltage to a hysteresis band. In one aspect, the hysteresis circuitry 212 of FIG. 2 can provide a means for performing the hysteretic comparison. In some aspects, the hysteresis circuitry can include a Vdroop threshold comparator 604 (see FIG. 6) configured to compare the rail voltage to the hysteresis band. The hysteresis circuitry can include a recovery threshold comparator 606 (see FIG. 6) configured to compare the rail voltage to the hysteresis band. The hysteresis circuitry can further include a rail event signal generator 608 (see FIG. 6) that generates a rail event signal based on the outputs of the recovery threshold comparator and the Vdroop threshold comparator.

At 806, the method includes a process of stabilizing the rail voltage based on a result of the hysteretic comparison. In one aspect, one or more cores/processors (e.g., processor 110 of FIG. 1) can provide a means for stabilizing the rail voltage. For example, a processor can receive the rail event signal from the hysteresis circuitry. Based on the rail event signal, the processor can adjust the performance and/or processing load of the apparatus to control the rail current in order to stabilize the rail voltage. For example, the processor can adjust the performance according to the reactive rail voltage management process described above in relation to FIG. 7. In some aspects, the processor can throttle the performance of the apparatus by reducing a supply voltage or a clock frequency of one or more components of the apparatus. In some aspects, the processor can throttle the performance by reducing a number of active components of the apparatus. In some aspects, the processor can throttle the performance by disabling at least one of a clock signal or a power supply of one or more components of the apparatus.

In one aspect, the method can include a process of comparing the rail voltage to the voltage deviation threshold value; and detecting a voltage deviation event upon detecting that the rail voltage is equal to or less than the voltage deviation threshold value.

In one aspect, the method can include a process of comparing the rail voltage to the recovery threshold value; and detecting a recovery event upon detecting that the rail voltage is equal to or greater than the recovery threshold value. In one aspect, the method can include a process of detecting the rail voltage at a power entry point of an on-die power delivery network of the apparatus. In one aspect, the method can include a process of generating a control signal based on the hysteretic comparison, the control signal configured to adjust a performance level of the apparatus.

Of course, in the above examples, the described components are merely provided as examples, and other means for carrying out the described functions may be included within various aspects of the present disclosure, including any other suitable apparatus or means described in any one of the FIGS. 1, 2, and 6, and utilizing, for example, the processes and/or algorithms described herein in relation to FIGS. 3-5 and 7.

The following provides an overview of aspects of the present disclosure:

Aspect 1: An apparatus comprising: a system-on-chip (SoC); and a power management integrated circuit (PMIC) configured to supply power to the SoC, the SoC being configured to: detect a rail voltage associated with the SoC; perform a hysteretic comparison of the rail voltage to a hysteresis band; and stabilize the rail voltage based on a result of the hysteretic comparison.

Aspect 2: The apparatus of aspect 1, wherein the SoC is further configured to: compare the rail voltage to a voltage deviation threshold value of the hysteresis band; and detect a voltage deviation event upon detecting that the rail voltage is equal to or less than the voltage deviation threshold value.

Aspect 3: The apparatus of aspect 2, wherein the SoC is further configured to: compare the rail voltage to a recovery threshold value of the hysteresis band; and detect a recovery event upon detecting that the rail voltage is equal to or greater than the recovery threshold value.

Aspect 4: The apparatus of any of aspect 1, 2, or 3, wherein the SoC is further configured to: detect the rail voltage at a power entry point of an on-die power delivery network of the SoC.

Aspect 5: The apparatus of any of aspect 1, 2, or 3, wherein the SoC is further configured to: generate a control signal based on the hysteretic comparison, the control signal configured to adjust a performance level of the SoC.

Aspect 6: The apparatus of aspect 5, wherein the SoC is further configured to stabilize the rail voltage according to the control signal, comprising at least one of: reducing at least one of a supply voltage or a clock frequency of one or more components of the SoC; reduce a number of active components of the SoC; or disable at least one of a clock signal or a power supply of one or more components of the SoC.

Aspect 7: The apparatus of aspect 5, wherein the SoC is further configured to restore the rail voltage according to the control signal, comprising at least one of: increasing at least one of a supply voltage or a clock frequency of one or more components of the SoC; increasing a number of active components of the SoC; or enabling at least one of a clock signal or a power supply of one or more components of the SoC.

Aspect 8: A method of managing a rail voltage at an apparatus, comprising: detecting a rail voltage associated with the apparatus; performing a hysteretic comparison of the rail voltage to a hysteresis band; and stabilizing the rail voltage based on a result of the hysteretic comparison.

Aspect 9: The method of aspect 8, further comprising: comparing the rail voltage to a voltage deviation threshold value of the hysteresis band; and detecting a voltage deviation event upon detecting that the rail voltage is equal to or less than the voltage deviation threshold value.

Aspect 10: The method of aspect 9, further comprising: comparing the rail voltage to a recovery threshold value of the hysteresis band; and detecting a recovery event upon detecting that the rail voltage is equal to or greater than the recovery threshold value.

Aspect 11: The method of any of aspect 8, 9, or 10, further comprising: detecting the rail voltage at a power entry point of an on-die power delivery network of the apparatus.

Aspect 12: The method of any of aspect 8, 9, or 10, further comprising: generating a control signal based on the hysteretic comparison, the control signal configured to adjust a performance level of the apparatus.

Aspect 13: The method of aspect 12, wherein the stabilizing the rail voltage comprises at least one of: reducing at least one of a supply voltage or a clock frequency of one or more components of the apparatus; reduce a number of active components of the apparatus; or disable at least one of a clock signal or a power supply of one or more components of the apparatus.

Aspect 14: The method of aspect 12, further comprising restoring the rail voltage according to the control signal, comprising at least one of: increasing at least one of a supply voltage or a clock frequency of one or more components of the apparatus; increasing a number of active components of the apparatus; or enabling at least one of a clock signal or a power supply of one or more components of the apparatus.

Aspect 15: A system on a chip (SoC) comprising: means for detecting a rail voltage associated with the SoC; means for performing a hysteretic comparison of the rail voltage to a hysteresis band; and means for stabilizing the rail voltage based on a result of the hysteretic comparison.

Aspect 16: The SoC of aspect 15, further comprising: means for comparing the rail voltage to a voltage deviation threshold value of the hysteresis band; and means for detecting a voltage deviation event upon detecting that the rail voltage is equal to or less than the voltage deviation threshold value.

Aspect 17: The SoC of aspect 16, further comprising: means for comparing the rail voltage to a recovery threshold value of the hysteresis band; and means for detecting a recovery event upon detecting that the rail voltage is equal to or greater than the recovery threshold value.

Aspect 18: The SoC of any of aspect 15, 16, or 17, further comprising: means for detecting the rail voltage at a power entry point of an on-die power delivery network of the SoC.

Aspect 19: The SoC of any of aspect 15, 16, or 17, wherein the means for stabilizing the rail voltage is configured to, at least one of: reduce at least one of a supply voltage or a clock frequency of one or more components of the SoC; reduce a number of active components of the SoC; or disable at least one of a clock signal or a power supply of one or more components of the SoC.

Aspect 20: The SoC of any of aspect 15, 16, or 17, wherein the means for stabilizing the rail voltage is configured to, at least one of: increase at least one of a supply voltage or a clock frequency of one or more components of the SoC; increase a number of active components of the SoC; or enable at least one of a clock signal or a power supply of one or more components of the SoC.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two objects. For example, if object A physically touches object B, and object B touches object C, then objects A and C may still be considered coupled to one another-even if they do not directly physically touch each other. For instance, a first object may be coupled to a second object even though the first object is never directly physically in contact with the second object. The terms “circuit” and “circuitry” are used broadly, and intended to include both hardware implementations of electrical devices and conductors that, when connected and configured, enable the performance of the functions described in the present disclosure, without limitation as to the type of electronic circuits, as well as software implementations of information and instructions that, when executed by a processor, enable the performance of the functions described in the present disclosure.

One or more of the components, steps, features and/or functions illustrated in FIGS. 1-8 may be rearranged and/or combined into a single component, step, feature or function or embodied in several components, steps, or functions. Additional elements, components, steps, and/or functions may also be added without departing from novel features disclosed herein. The apparatus, devices, and/or components illustrated in FIGS. 1-8 may be configured to perform one or more of the methods, features, or steps described herein. The novel algorithms described herein may also be efficiently implemented in software and/or embedded in hardware.

Any reference to an element herein using a designation e.g., “first,” “second,” and so forth does not generally limit the quantity or order of those elements. Rather, these designations are used herein as a convenient way of distinguishing between two or more elements or instances of an element. Thus, a reference to first and second elements does not mean that only two elements can be employed, or that the first element must precede the second element.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover: a; b; c; a and b; a and c; b and c; and a, b and c. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f) unless the element is expressly recited using the phrase “means for” or, in the case of a method claim, the element is recited using the phrase “step for.”

What is claimed is:

1. An apparatus comprising:
a system-on-chip (SoC); and
a power management integrated circuit (PMIC) configured to supply power to the SoC, the SoC being configured to:
detect a rail voltage associated with the SoC;
perform a hysteretic comparison of the rail voltage to a hysteresis band; and
stabilize the rail voltage based on a result of the hysteretic comparison.

2. The apparatus of claim 1, wherein the SoC is further configured to:
compare the rail voltage to a voltage deviation threshold value of the hysteresis band; and
detect a voltage deviation event upon detecting that the rail voltage is equal to or less than the voltage deviation threshold value.

3. The apparatus of claim 2, wherein the SoC is further configured to:
compare the rail voltage to a recovery threshold value of the hysteresis band; and
detect a recovery event upon detecting that the rail voltage is equal to or greater than the recovery threshold value.

4. The apparatus of claim 1, wherein the SoC is further configured to:
detect the rail voltage at a power entry point of an on-die power delivery network of the SoC.

5. The apparatus of claim 1, wherein the SoC is further configured to:
generate a control signal based on the hysteretic comparison, the control signal configured to adjust a performance level of the SoC.

6. The apparatus of claim 5, wherein the SoC is further configured to stabilize the rail voltage according to the control signal, comprising at least one of:
reducing at least one of a supply voltage or a clock frequency of one or more components of the SoC;
reduce a number of active components of the SoC; or
disable at least one of a clock signal or a power supply of one or more components of the SoC.

7. The apparatus of claim 5, wherein the SoC is further configured to restore the rail voltage according to the control signal, comprising at least one of:
increasing at least one of a supply voltage or a clock frequency of one or more components of the SoC;
increasing a number of active components of the SoC; or
enabling at least one of a clock signal or a power supply of one or more components of the SoC.

8. A method of managing a rail voltage at an apparatus, comprising:
detecting a rail voltage associated with the apparatus;
performing a hysteretic comparison of the rail voltage to a hysteresis band; and
stabilizing the rail voltage based on a result of the hysteretic comparison.

9. The method of claim 8, further comprising:
comparing the rail voltage to a voltage deviation threshold value of the hysteresis band; and
detecting a voltage deviation event upon detecting that the rail voltage is equal to or less than the voltage deviation threshold value.

10. The method of claim 9, further comprising:
comparing the rail voltage to a recovery threshold value of the hysteresis band; and
detecting a recovery event upon detecting that the rail voltage is equal to or greater than the recovery threshold value.

11. The method of claim 8, further comprising:
detecting the rail voltage at a power entry point of an on-die power delivery network of the apparatus.

12. The method of claim 8, further comprising:
generating a control signal based on the hysteretic comparison, the control signal configured to adjust a performance level of the apparatus.

13. The method of claim 12, wherein the stabilizing the rail voltage comprises at least one of:
reducing at least one of a supply voltage or a clock frequency of one or more components of the apparatus;
reduce a number of active components of the apparatus; or
disable at least one of a clock signal or a power supply of one or more components of the apparatus.

14. The method of claim 12, further comprising restoring the rail voltage according to the control signal, comprising at least one of:
increasing at least one of a supply voltage or a clock frequency of one or more components of the apparatus;
increasing a number of active components of the apparatus; or
enabling at least one of a clock signal or a power supply of one or more components of the apparatus.

15. A system on a chip (SoC) comprising:
means for detecting a rail voltage associated with the SoC;
means for performing a hysteretic comparison of the rail voltage to a hysteresis band; and
means for stabilizing the rail voltage based on a result of the hysteretic comparison.

16. The SoC of claim 15, further comprising:
means for comparing the rail voltage to a voltage deviation threshold value of the hysteresis band; and
means for detecting a voltage deviation event upon detecting that the rail voltage is equal to or less than the voltage deviation threshold value.

17. The SoC of claim 16, further comprising:
means for comparing the rail voltage to a recovery threshold value of the hysteresis band; and
means for detecting a recovery event upon detecting that the rail voltage is equal to or greater than the recovery threshold value.

18. The SoC of claim 15, further comprising:
means for detecting the rail voltage at a power entry point of an on-die power delivery network of the SoC.

19. The SoC of claim 15, wherein the means for stabilizing the rail voltage is configured to, at least one of:
reduce at least one of a supply voltage or a clock frequency of one or more components of the SoC;
reduce a number of active components of the SoC; or
disable at least one of a clock signal or a power supply of one or more components of the SoC.

20. The SoC of claim 15, wherein the means for stabilizing the rail voltage is configured to, at least one of:
increase at least one of a supply voltage or a clock frequency of one or more components of the SoC;
increase a number of active components of the SoC; or
enable at least one of a clock signal or a power supply of one or more components of the SoC.
